(19) United States
(12) Patent Application Publication
(10) Pub. No.: US 2004/0155350 A1
(43) Pub. Date: Aug. 12, 2004

(54) Semiconductor device having multi-layer interconnection structure

(76) Inventors: Akira Matumoto, Kanagawa (JP); Manabu Iguchi, Kanagawa (JP); Masahiro Komuro, Kanagawa (JP); Tadashi Fukase, Kanagawa (JP)

Correspondence Address: YOUNG & THOMPSON, 745 SOUTH 23RD STREET 2ND FLOOR, ARLINGTON, VA, 22202

(21) Appl. No.: 10/769,868

(22) Filed: Feb. 3, 2004

(30) Foreign Application Priority Data
Feb. 6, 2003 (JP) 2003-030092
Sep. 17, 2003 (JP) 2003-324209

(51) Int. Cl. H01L 23/48

(52) U.S. Cl. 257/758

(57) ABSTRACT

A semiconductor device is provided which is capable of preventing corrosion of circuit portion and ensuring high reliability by optimizing a construction of outer-surrounding protecting walls that surround an internal element region to completely stop invasion of water from an edge portion of a semiconductor chip. The outer-surrounding protecting walls made up of a wiring layer and a via layer are formed in a manner to surround the internal element region and that a distance between an edge portion of the semiconductor chip and the outermost-surrounding protecting wall is 30 μm. The outer-surrounding protecting wall is so formed as to doubly or more surround the internal element region.

### BACKGROUND OF THE INVENTION

1. Field of the Invention

The present invention relates to a semiconductor device having multi-layer interconnection structure and more particularly to structure of outer-surrounding protecting walls that surround an internal element region to prevent an invasion of water, which is formed between an edge portion of a semiconductor substrate and the internal element region in which two or more elements are formed.

The present application claims two priorities of Japanese Patent Application No.2003-030092 filed on Feb. 6, 2003 and Japanese Patent Application No.2003-324209 filed on Sep. 17, 2003, which are hereby incorporated by reference.

2. Description of the Related Art

An invasion of water is one of factors that greatly decrease reliability in semiconductor devices. A semiconductor device, after having been first formed in a wafer state, is split and cut by dicing technology so as to form a semiconductor chip. However, there is a fear that, during and/or after a dicing process, water invades from an edge portion of the semiconductor chip into the semiconductor device. Particularly, there is a problem in that, in the case of multi-layer interconnection structure using a low-dielectric film as an interlayer dielectric (interlayer insulating film), since the low-dielectric film generally has a low density, water easily permeates the dielectric film, which makes the problem more serious.

To solve this problem, it is known that, between an edge portion of a semiconductor chip and an internal element region including a bonding pad is installed an outer-surrounding protecting wall which penetrates each of two or more interlayer dielectrics (interlayer insulating films) formed on a semiconductor substrate to prevent water from being invaded and which, as a whole and in an integral manner, surrounds the internal element region.

The outer-surrounding protecting wall is made up of an insulating film or a metal film being highly resistant to water, or a stacked film obtained by combining the insulating film with the metal film and is formed so as to be in a ring-shaped state in a manner to fully surround the internal element region. Such the technology is disclosed in Japanese Patent Application Laid-open Nos. Hei 4-279050 and JP2000-150429, and U.S. Pat. No. 6,137,155. A known maximum diameter of a silicon wafer is 300 mm and such the silicon wafer, after having been produced, is split and cut to many chips.

FIG. 3 is a plan view illustrating part of a silicon wafer obtained by being split and cut. The silicon wafer is adhered to an adhering sheet (not shown) and polished and cut, by using a dicing machine, along a central line 101 (any silicon wafer has not always this line) between chips. A margin to polish and cut the silicon wafer is almost the same as a width of a dicing blade which is about 30 μm. An outer-surrounding protecting wall 103 is formed between an edge portion 102 of a semiconductor chip and an internal element region 104. The internal element region 104 includes a bonding pad (not shown) and, generally, the bonding pad is placed in an outer-surrounding portion of the internal element region 104. Therefore, the outer-surrounding protecting wall 103 is formed between the bonding pad and the chip edge portion.

FIG. 4 is a cross-sectional view of a silicon chip 105 which is disclosed in Japanese Patent Application Laid-open No. 2000-150429, having an outer-surrounding protecting wall 103. The silicon chip 105, as shown in FIG. 4, is made up of a silicon substrate 106 including a diffusion region of a semiconductor device, a lower insulating film 107 including a gate electrode and a contact hole of the semiconductor device, a first interlayer dielectric 108, a second interlayer dielectric 111, a third interlayer dielectric 114, and metal wirings (described below) formed in the interlayer dielectrics 108, 111, and 114. In an internal element region 104 in the silicon chip 105, a first metal wiring 110 and a second metal wiring 115 are formed. The first metal wiring 110 and second metal wiring 115 are connected, whenever necessary, via a metal plug 112 which fills up a via hole. The outer-surrounding protecting wall 103 is formed in the first interlayer dielectric 108 and made up of ring-shaped metal wirings 109, 113, and 116 in a manner to surround the internal element region 104. The metal wiring 109 is formed simultaneously with the first metal wiring 110. The metal wiring 113 is formed simultaneously with the metal plug 12 (hereinafter referred to as via plug). The metal wiring 116 is formed simultaneously with second metal wiring 115. By forming the outer-surrounding protecting wall 103 as above, invasion of water from an edge portion 102 of a silicon chip into the internal element region 104 can be prevented and corrosion of the insulating layers 108, 111, and 114 and metal wirings 110 and 115 in the internal element region 104 can be also prevented.

However, inventors of the present invention have found from a detailed research on a diced state of a silicon wafer that there is a following problem when such the outer-surrounding protecting wall as described above is formed. FIG. 5 is an expanded plan view illustrating a diced portion of a silicon wafer obtained immediately after the silicon wafer has been cut by using dicing technology. In FIG. 5, same reference numbers as those in FIG. 3 are assigned to components having same functions as shown in FIG. 3. As shown in FIG. 5, a chipped portion 120 including a flawed portion, cracked portion or a like and an interlayer dielectric peeled portion 121 along an edge portion 102 of a silicon chip toward an internal element region 104 occur due to shaking or deterioration of a blade. In some cases, a maximum invasion depth of the chipped portion 120 and interlayer dielectric peeled portion 104 from the edge portion 102 of the silicon chip is 25 μm. Therefore, if the outer-surrounding protecting wall 103 is too near to the edge portion 102 of the silicon chip, there is a possibility that the outer-surrounding protecting wall 103 is broken due to chipping during a dicing process. Especially, when a low dielectric constant film is employed as the interlayer dielectric film, since a mechanical strength of the low dielectric film is low and adherence to other films is weak, the interlayer dielectric peeled portion 121 easily occurs in the vicinity of diced region of the silicon wafer.

If metal making up the outer-surrounding protecting wall 103 is eroded completely due to the invasion of water from the edge portion 102 of the silicon chip, the outer-surrounding protecting wall 103 becomes defenseless against further invasion of water. Use of the outer-surrounding protecting wall 103 having a width of several tens μm being so wide that the outer-surrounding protecting wall 103 is not completely eroded may be possible. However, if the width of the metal wirings 109, 116, and 113 in the outer-surrounding protecting wall 103 in FIG. 4 is several tens times larger than a width (1 μm or less) of the metal wiring in the internal element region 104, uniform formation of a trench or uniform embedding of the metal in the insulating film in a region of the outer-surrounding protecting wall 103 and the internal element region 104 is made difficult and practically impossible.

### SUMMARY OF THE INVENTION

In view of the above, it is an object of the present invention to provide a semiconductor device which is capable of preventing corrosion of circuit portions and ensuring high reliability by optimizing an outer-surrounding protecting wall that surrounds an internal element region to completely stop the invasion of water from an edge portion of a semiconductor chip.

According to a first aspect of the present invention, there is provided a semiconductor device having multi-layer inter-connection structure which includes two or more elements, two or more wiring layers and two or more specified insulating film formed on its semiconductor substrate, the semiconductor device including:

outer-surrounding protecting walls each being formed between an edge portion of the semiconductor substrate and an internal element region in which the two or more elements are formed, in a manner to penetrate each of the two or more specified insulating film deposited on the semiconductor substrate and so as to surround, as a whole and in an integral manner, the internal element region; and

wherein, the outer-surrounding protecting walls are so formed as to doubly or more surround the internal element region. According to a second aspect of the present invention, there is provided a semiconductor device having multi-layer interconnection structure which includes two or more elements, two or more wiring layers and two or more specified insulating film formed on its semiconductor substrate, the semiconductor device including:

outer-surrounding protecting walls each being formed between an edge portion of the semiconductor substrate and an internal element region in which the two or more elements are formed, in a manner to penetrate each of the two or more specified insulating film deposited on the semiconductor substrate and so as to surround, as a whole and in an integral manner, the internal element region; and

wherein a distance between an edge portion of the semiconductor substrate and an outermost one of the outer-surrounding protecting walls is larger than a chipping depth. (typical chipping depth is 25 μm and the chipping here denotes missing, flaw, crack, or a like of the chip edge portion).

In the foregoing, a preferable mode is one wherein a distance between an edge portion of the semiconductor substrate and the outermost one of the outer-surrounding protecting walls is 30 μm or more.

According to a third aspect of the present invention, there is provided a semiconductor device having multi-layer inter-connection structure which includes two or more elements, two or more wiring layers and two or more specified insulating film formed on its semiconductor substrate, the semiconductor device including:

outer-surrounding protecting walls each being formed between an edge portion of the semiconductor substrate and an internal element region in which the two or more elements are formed, in a manner to penetrate each of the two or more specified insulating film deposited on the semiconductor substrate and to surround, as a whole and in an integral manner, the internal element region; and

wherein the outer-surrounding protecting walls are so formed as to doubly or more surround the internal element region and wherein a distance between an edge portion of the semiconductor substrate and the outer-surrounding protecting wall being placed in an outermost surrounding position is 30 μm or more.

In the foregoing first, second and third aspects, a preferable mode is one wherein the outer-surrounding protecting walls are made up of two or more outer wiring layers formed simultaneously with and with same materials as for the two or more wiring layers in the internal element region and of outer via plugs formed simultaneously with and with same materials as for via plugs connecting the two or more wiring layers in the internal element region.

Another preferable mode is one wherein the wiring layers and the via plugs are made of an alloy containing aluminum as a main material, copper, or an alloy containing copper as a main material.

Still another preferable mode is one wherein the via plugs making up the outer-surrounding protecting walls are connected in a ring-shaped manner so as to surround the internal element region.

A further preferable mode is one wherein at least one of the two or more specified insulating films is a single film or a stacked film made of at least one selected from a group of SiO₂ (silicon dioxide), L-Oₓ (ladder siloxane hydride), HSQ (hydrogen silisesquioxane), SiOC (silicon oxide carbide), SiLK (polyphenylen), SiOF (silicon oxide with fluorine), SiCN (silicon carbide nitride), SiC (silicon carbide), SiN (silicon nitride), SiCOH (silicon carbide hydroxide), and SiON (silicon oxide nitride). An additional preferable mode is one wherein said specified insulating films each include an interlayer dielectric.

With the above configuration, the semiconductor device has multi-layer interconnection structure being provided with outer-surrounding protecting walls made up of the wiring layer and the via layer placed in a manner to surround an internal element region, in which a distance between the outer-surrounding protecting wall being placed in an outermost surrounding position and an edge portion of the semiconductor chip is a chipping depth or more, more particularly, 30 μm or more, or the outer-surrounding protecting walls are doubly or more formed in structure. Therefore, it is made possible to prevent the outer-surrounding protecting wall being broken due to chipping that may occur at the edge portion of the semiconductor chip during a dicing process or peeling of the interlayer dielectric. Moreover, by doubly or more forming the outer-surrounding protecting walls, even when the outer-surrounding protecting wall placed outside is completely eroded due to invasion of water from the edge portion of the semiconductor chip, the invasion of water into the internal element region can be prevented by the outer-surrounding protecting wall placed inside.

### BRIEF DESCRIPTION OF THE DRAWINGS

The above and other objects, advantages, and features of the present invention will be more apparent from the following description taken in conjunction with the accompanying drawings in which:

FIG. 1 is a cross-sectional view of a semiconductor chip according to an embodiment of the present invention;

FIGS. 2A to 2D are diagrams illustrating a method of manufacturing a semiconductor chip, in order of processes, according to the embodiment of the present invention;

FIG. 3 is a plan view illustrating part of a conventional silicon wafer;

FIG. 4 is a cross-sectional view of a semiconductor chip having a conventional outer-surrounding protecting wall; and

FIG. 5 is an expanded plan view illustrating a diced portion of the conventional silicon wafer obtained immediately after the silicon wafer has been cut by dicing technology.

### DETAILED DESCRIPTION OF THE PREFERRED EMBODIMENTS

Best modes of carrying out the present invention will be described in further detail using various embodiments with reference to the accompanying drawings.

### Embodiment

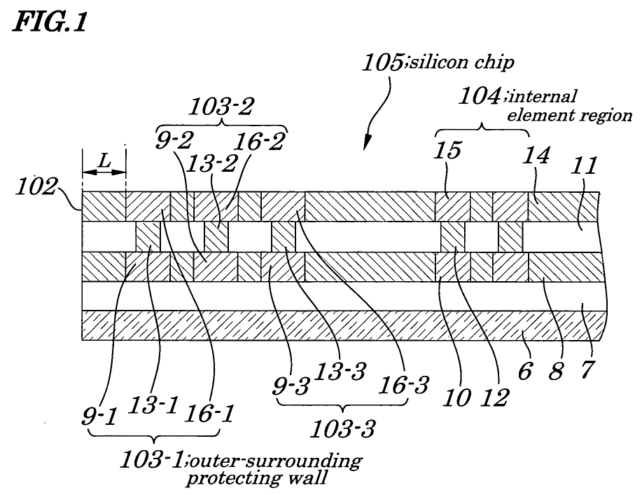

FIG. 1 is a cross-sectional view of a silicon chip according to one embodiment of the present invention. As shown in FIG. 1, a silicon chip 105 is made up of a silicon substrate 6 on which an impurity diffusion layer or a like (not shown) is formed, an insulating layer 7 on which a gate electrode (not shown) and a contact hole (not shown) is formed, and multi-layered insulating films and wiring layers formed sequentially on the insulating layer 7. Two-layered wiring layers are formed by a first wiring layer insulating film 8 in which a first wiring 10 is formed, a second wiring layer insulating film 14 in which a second wiring 15 is formed, and a via layer insulating film 11 formed between the first wiring layer insulating film 8 and the second wiring insulating film 14, in which a via plug 12 is formed that is used to connect the first wiring 10 to the second wiring 15. To increase the wiring layer, a pair of insulating films made up of the via layer insulating film 11 and second wiring layer insulating film 14 is sequentially stacked. In the embodiment, to simplify and clarify the description of the invention, a case where two-layered wirings are formed is explained.

As described above, an internal wiring region is the same as that in the conventional multi-layer interconnection silicon integrated circuit chip. In the embodiment, outer-surrounding protecting walls 103-1, 103-2, and 103-3 are trebly formed as shown in FIG. 1. Though its plan view is omitted, the treble outer-surrounding protecting walls 103-1, 103-2, and 103-3 are formed and connected in a ring-shaped manner so as to trebly surround an internal element region 104. A width of each of the treble outer-surrounding protecting walls 103-1, 103-2, and 103-3 is about 1 μm and an interval among the trebly formed outer-surrounding protecting walls 103-1, 103-2, and 103-3 is about 1 μm.

As shown in the same figure, the outer-surrounding protecting wall 103-1 is made up of a first wiring 9-1, second wiring 16-1, and via plug 13-1. The configurations of the outer-surrounding protecting walls 103-2 and 103-3 are the same as those in the outer-surrounding protecting wall 103-1 and their descriptions are omitted accordingly. Materials for the treble outer-surrounding protecting walls 103-1, 103-2, and 103-3 are the same for the internal element region 104 and both the treble outer-surrounding protecting walls 103-1, 103-2, and 103-3 and the internal element region 104 are formed at the same time. A distance “L” (see FIG. 1) between the outer-surrounding protecting wall 103-1 being placed in an outermost surrounding position and an edge portion 102 of the silicon chip 105 is 30 μm. A shaving margin of the edge portion 102 of the silicon chip 105 differs depending on a dicing machine and a dicing blade and, therefore, the position of the outer-surrounding protecting wall 103-1 being placed in the outermost surrounding position is determined depending on the shaving margin. In the case of general dicing, a shaving margin is about 30 μm.

In the embodiment, the outer-surrounding protecting walls are trebly formed in structure as described above. However, so long as the outer-surrounding protecting walls are formed doubly or more, the outer-surrounding protecting wall placed inside can prevent water from invading into the internal element region, even when the outer-surrounding protecting wall placed outside is completely eroded due to invasion of water from the edge portion of the semiconductor chip.

Since a width of one outer-surrounding protecting wall is about 1 μm, even if treble or more outer-surrounding protecting walls are formed, almost no increase in a chip area occurs. In the embodiment, the distance L (FIG. 1) between the edge portion 102 of the semiconductor chip 105 and the outermost-surrounding protecting wall 103-1 placed in an outermost surrounding position is set to be 30 μm. In fact it is preferable that the distance L is set to 30 μm or more, if necessary. As a material for the first wiring layer insulating film 8, the via layer insulating filmll, and the second wiring layer insulating film 14, one material can be selected out of materials including SiO₂ (silicon dioxide), L-Oₓ (ladder-siloxane hydride), HSQ (hydrogen silisesquioxane), SiOC (silicon oxide carbide), SiLK (polyhphenylene), SiOF (silicon oxide with fluorine), SiCN (silicon carbide nitride), SiC (silicon carbide), SiN (silicon nitride), SiCOH (silicone carbide hydroxide), and SiON (silicon oxide nitride). A stacked film made of the above materials may be employed. As a material for the first wirings 10, 9-1 to 9-3, the via plugs 12, 13-1 to 13-3, and the second wirings 15, 16-1 to 16-3, an alloy containing Al as its main material, Cu, or alloy containing Cu as its basis material may be employed.

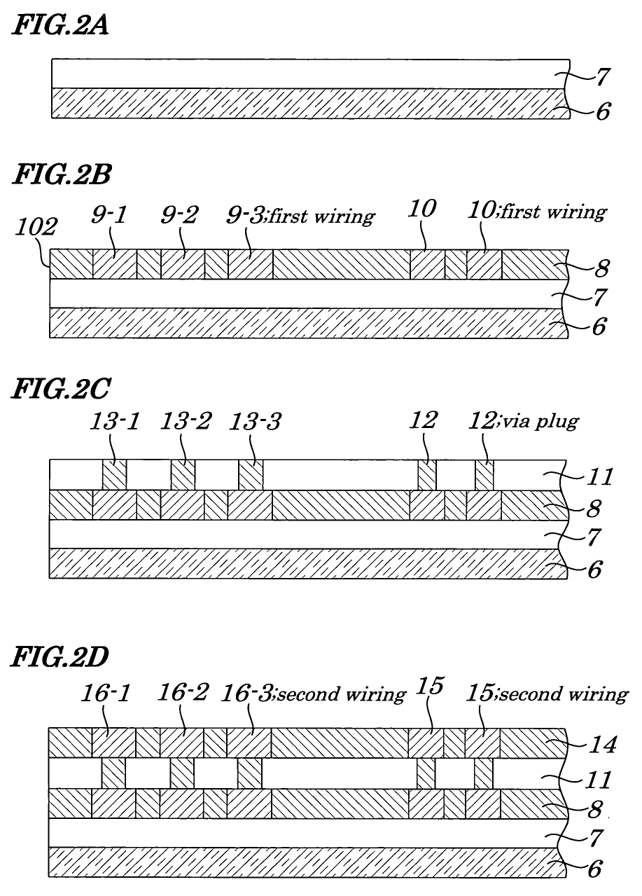

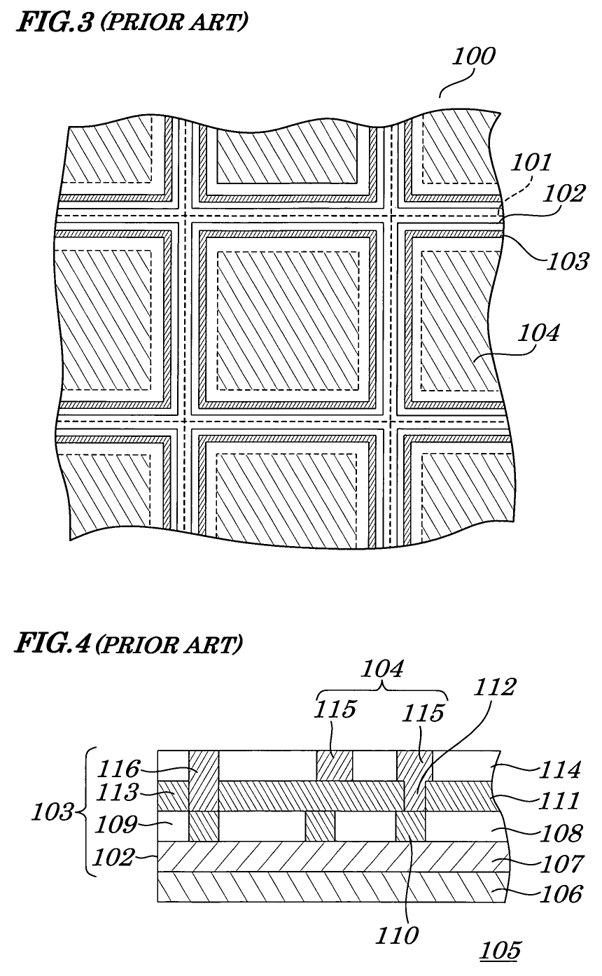

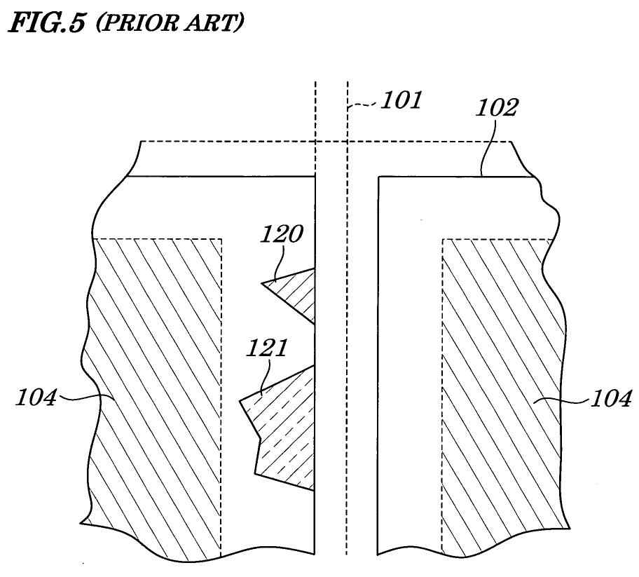

Next, a method for manufacturing the silicon chip 105 used in the embodiment shown in FIG. 1 is described by referring to FIGS. 2A to 2D. As shown in FIG. 2A, a source region (not shown), drain region (not shown), or isolation region (not shown) are first formed in the silicon substrate 6 making up a semiconductor device. Next, on the silicon substrate 6 is formed the insulating film 7 in which elements being made up of such as a gate electrode (not shown) and/or a contact hole (not shown) are formed. Then, as shown in FIG. 2B, on the insulating layer 7 containing such elements as above formed on the silicon substrate 6 are formed the first wiring layer insulating film 8, the first wiring 10 to be formed in the first wiring layer insulating film 8, and the first wirings 9-1 to 9-3 each making up each of the treble outer-surrounding protecting walls 103-1, 103-2, and 103-3. The distance between an outer side edge of the first wiring 9-1 and the edge portion 102 of the silicon chip 105 (defined after being diced) is 30 μm.

The first wiring layer insulating film 8 is obtained by deposition of SiO₂ using a CVD (Chemical Vapor Deposition) method. The first wirings 10, 9-1 to 9-3 are obtained by forming a trench on the SiO₂ film, by depositing copper throughout the surface of the SiO₂ film and the trench using a plating method and by removing copper existing in portions except the trench using a CMP (Chemical Mechanical Polishing) method. This method is a well-known copper-embedded wiring method and its detailed description is omitted accordingly.

Next, as shown in FIG. 2C, on the first wiring layer insulating film 8, the first wiring 10, and the first wirings 9-1 to 9-3 making up the outer-surrounding protecting walls 103-1, 103-2, and 103-3 is formed the first via layer insulating film 11, in which the via plug 12 and the via plugs 13-1 to 13-3 making up the outer-surrounding protecting walls 103-1, 103-2, and 103-3 are formed. The via plugs 13-1 to 13-3 each having a width being narrower than that of each of the first wirings 9-1 to 9-3 are formed in a ring-shaped manner. In the embodiment shown in FIGS. 2B to 2D, on the first wiring 9-1 is formed only one via plug 13-1 to be connected with the first wiring 9-1, however, two or more via plugs 13-1 may be formed.

As a material for the via layer insulating film 11, one material can be selected out of materials including SiO₂ (silicon dioxide), L-Oₓ (ladder-siloxane hydride), HSQ (hydrogen silisesquioxane), SiOC (silicon oxide carbide), SiLK (polyhphenylene), SiOF (silicon oxide with fluorine), SiCN (silicon carbide nitride), SiC (silicon carbide); SiN (silicon nitride), SiCOH (silicone carbide hydroxide), and SiON (silicon oxide nitride). A stacked film made of the above materials may be also employed. Moreover, the via plugs 12, 13-1 to 13-3 are formed by the copper-embedded wiring method as in the case of the first wiring 10.

Then, as shown in FIG. 2D, on the via layer insulating film 11 is formed the second wiring layer insulating film 14, in which the second wiring 15, and the second wirings 16-1 to 16-3 making up the outer-surrounding protecting walls 103-1, 103-2, and 103-3 are formed. The second wiring layer insulating film 14 is formed in the same manner as employed in the via layer insulating film 11. The second wirings 15, 16-1 to 16-3 are formed by the copper-embedded wiring method as in the case of the first wiring 10.

To make the wiring be multi-layered, for example, be three-layered or more, processes described in FIGS. 2C and 2D are repeated. The processes described in FIGS. 2C and 2D are those employed in a manufacturing method called a “single damascene”, however, another manufacturing method called a “dual damascene” in which the via plug and the second wiring are formed at a same time may be used. Finally, a passivation film (not shown) made of a nitride film, polyimide film, or a like are formed to obtain a multi-layer interconnection silicon integrated circuit chip having the outer-surrounding protecting wall of treble structure as shown in FIG. 1.

It is apparent that the present invention is not limited to the above embodiments but may be changed and modified without departing from the scope and spirit of the invention. For example, in the above embodiment, the same metal wirings that are used in the internal element region are employed in the outer-surrounding protecting wall, however, the present invention is not limited to this. A dielectric film having highly humidity-resistance such as a nitride film, instead of metal wirings, may be employed or a stacked film made up of the highly humidity-resistant dielectric film and metal film may be used as the outer-surrounding protecting wall. Moreover, it is preferable that both the outer-surrounding protecting wall and the internal element region are formed at a same time, however, each of them may be manufactured in an exclusive process. For example, the outer-surrounding protecting wall may be formed in a manner that a trench is formed in one time in a multi-layered interlayer dielectric and the trench is filled up with a metal or a highly humidity-resistant dielectric film. It is needless to say that, when junction processes between metals of different kinds, between dielectric films of different types, and between the dielectric film and metal are performed, a material having strong adherence at an interface surface is selected and a barrier metal such as titanium nitride (TiN) or a like is introduced.

What is claimed is:

1. A semiconductor device having multi-layer interconnection structure which comprises two or more elements, two or more wiring layers and two or more specified insulating film formed on its semiconductor substrate, said semiconductor device comprising:
outer-surrounding protecting walls each being formed between an edge portion of said semiconductor substrate and an internal element region in which said two or more elements are formed, in a manner to penetrate each of said two or more specified insulating film deposited on said semiconductor substrate and so as to surround, as a whole and in an integral manner, said internal element region; and
wherein, said outer-surrounding protecting walls are so formed as to doubly or more surround said internal element region.

2. The semiconductor device having the multi-layer interconnection structure according to claim 1, wherein said outer-surrounding protecting walls are made up of two or more outer wiring layers formed simultaneously with and with same materials as for said two or more wiring layers in said internal element region and of outer via plugs formed simultaneously with and with same materials as for via plugs connecting said two or more wiring layers in said internal element region.

3. The semiconductor device having the multi-layer interconnection structure according to claim 1, wherein said wiring layers and said via plugs are made of an alloy containing aluminum as a main material, copper, or an alloy containing copper as a main material.

4. The semiconductor device having the multi-layer interconnection structure according to claim 1, wherein said via plugs making up said outer-surrounding protecting walls are connected in a ring-shaped manner so as to surround said internal element region.

5. The semiconductor device having the multi-layer interconnection structure according to claim 1, wherein at least one of said two or more specified insulating films is a single film or a stacked film made of at least one selected from a group of SiO₂ (silicon dioxide), L-Oₓ (ladder siloxane hydride), HSQ (hydrogen silisesquioxane), SiOC (silicon oxide carbide), SiLK (polyphenylen), SiOF (silicon oxide with fluorine), SiCN (silicon carbide nitride), SiC (silicon carbide), SiN (silicon nitride), SiCOH (silicon carbide hydroxide), and SiON (silicon oxide nitride).

6. The semiconductor device having the multi-layer interconnection structure according to claim 1, wherein said specified insulating films each comprise an interlayer dielectric.

7. A semiconductor device having multi-layer interconnection structure which comprises two or more elements, two or more wiring layers and two or more specified insulating film formed on its semiconductor substrate, said semiconductor device comprising:
outer-surrounding protecting walls each being formed between an edge portion of said semiconductor substrate and an internal element region in which said two or more elements are formed, in a manner to penetrate each of said two or more specified insulating film deposited on said semiconductor substrate and so as to surround, as a whole and in an integral manner, said internal element region; and
wherein a distance between an edge portion of said semiconductor substrate and an outermost one of said outer-surrounding protecting walls is larger than a chipping depth.

8. The semiconductor device having the multi-layer interconnection structure according to claim 7, wherein a distance between an edge portion of said semiconductor substrate and said outermost one of said outer-surrounding protecting walls is 30 μm or more.

9. The semiconductor device having the multi-layer interconnection structure according to claim 7, wherein said outer-surrounding protecting walls are made up of two or more outer wiring layers formed simultaneously with and with same materials as for said two or more wiring layers in said internal element region and of outer via plugs formed simultaneously with and with same materials as for via plugs connecting said two or more wiring layers in said internal element region.

10. The semiconductor device having the multi-layer interconnection structure according to claim 7, wherein said wiring layers and said via plugs are made of an alloy containing aluminum as a main material, copper, or an alloy containing copper as a main material.

11. The semiconductor device having the multi-layer interconnection structure according to claim 7, wherein said via plugs making up said outer-surrounding protecting walls are connected in a ring-shaped manner so as to surround said internal element region.

12. The semiconductor device having the multi-layer interconnection structure according to claim 7, wherein at least one of said two or more specified insulating films is a single film or a stacked film made of at least one selected from a group of SiO₂ (silicon dioxide), L-Oₓ (ladder siloxane hydride), HSQ (hydrogen silisesquioxane), SiOC (silicon oxide carbide), SiLK (polyphenylen), SiOF (silicon oxide with fluorine), SiCN (silicon carbide nitride), SiC (silicon carbide), SiN (silicon nitride), SiCOH (silicon carbide hydroxide), and SiON (silicon oxide nitride).

13. The semiconductor device having the multi-layer interconnection structure according to claim 7, wherein said specified insulating films each comprise an interlayer dielectric.

14. A semiconductor device having multi-layer interconnection structure which comprises two or more elements, two or more wiring layers and two or more specified insulating film formed on its semiconductor substrate, said semiconductor device comprising:
outer-surrounding protecting walls each being formed between an edge portion of said semiconductor substrate and an internal element region in which said two or more elements are formed, in a manner to penetrate each of said two or more specified insulating film deposited on said semiconductor substrate and to surround, as a whole and in an integral manner, said internal element region; and
wherein said outer-surrounding protecting walls are so formed as to doubly or more surround said internal element region and wherein a distance between an edge portion of said semiconductor substrate and the outer-surrounding protecting wall being placed in an outermost surrounding position is 30 μm or more.

15. The semiconductor device having the multi-layer interconnection structure according to claim 14, wherein said outer-surrounding protecting walls are made up of two or more outer wiring layers formed simultaneously with and with same materials as for said two or more wiring layers in said internal element region and of outer via plugs formed simultaneously with and with same materials as for via plugs connecting said two or more wiring layers in said internal element region.

16. The semiconductor device having the multi-layer interconnection structure according to claim 14, wherein said wiring layers and said via plugs are made of an alloy containing aluminum as a main material, copper, or an alloy containing copper as a main material.

17. The semiconductor device having the multi-layer interconnection structure according to claim 14, wherein said via plugs making up said outer-surrounding protecting walls are connected in a ring-shaped manner so as to surround said internal element region.

18. The semiconductor device having the multi-layer interconnection structure according to claim 14, wherein at least one of said specified insulating films is a single film or a stacked film made of at least one selected from a group of SiO₂ (silicon dioxide), L-Oₓ (ladder siloxane hydride), HSQ (hydrogen silisesquioxane), SiOC (silicon oxide carbide), SiLK (polyphenylen), SiOF (silicon oxide with fluorine), SiCN (silicon carbide nitride), SiC (silicon carbide), SiN (silicon nitride), SiCOH (silicon carbide hydroxide), and SiON (silicon oxide nitride).

19. The semiconductor device having the multi-layer interconnection structure according to claim 14, wherein said specified insulating films each comprise an interlayer dielectric.
